(19) United States
(12) Patent Application Publication
(10) Pub. No.: US 2013/0076374 A1
(43) Pub. Date: Mar. 28, 2013

(54) CHARGED BODY SENSING SYSTEM

(71) Applicant: Li-Hsin HUANG, New Taipei City (TW)

(72) Inventor: Li-Hsin HUANG, New Taipei City (TW)

(21) Appl. No.: 13/624,109

(22) Filed: Sep. 21, 2012

Related U.S. Application Data
(60) Provisional application No. 61/537,590, filed on Sep. 22, 2011.

(51) Int. Cl. G01R 27/28

(52) U.S. Cl. 324/618

(57) ABSTRACT

A charged body sensing electrode is provided which includes a signal generator, a filter and a detector. The signal generator generates an excitation signal, and the filter is coupled to the signal generator and receives the excitation signal from the signal generator. The filter includes at least one charged body sensing unit. The detector is coupled to the filter and detects an output signal corresponding to the filter. Accordingly, when the charged body neared or touched the charged body sensing electrode, the output signal of the filter will be changed. The trajectory, the velocity or the location of the charged body, or the impedance variation of the charged body sensing unit can be obtained by the change of the output signal of the filter which is detected by the detector.

### FIELD OF THE INVENTION

The present invention relates to a charged body sensing system, and in particular to the change of the output signal of the filter can be detected by the detector to obtain the trajectory, the velocity or the location of the charged body, or an impedance variation of the charged body sensing unit.

### BACKGROUND OF THE INVENTION

There are many methods for an object proximity sensing and positioning. The methods include the capacitive sensing, an electromagnetic sensing, an optical sensing or an acoustic-type sensing, and so on.

The electromagnetic sensing is that when the induction is occurred, the magnetic flux will be changed, and the distance variation of the proximity object can be inferred.

The common method is electromagnetic sensing method, which has two sensing plates, one is a signal emitting terminal, and another is a signal receiving terminal. When the object closed to induce the variation of magnetic flux, the location of the object can be defined by the calculation.

Another common method is that a coil on the tuned circuit which is used as a sensing electrode. When the sensing electrode induces a metal object that is to be closed, the magnetic flux will be changed so that the amplitude of the oscillation signal is attenuated. In addition, the variation of the magnetic flux can be monitored by many methods.

The problem with existing designs for the electromagnetic proximity sensing includes: 1. human body cannot be sensed when the human is to be closed; and 2. The special electromagnetic pen is usually used for the touch panel and the electronic drawing application so that the cost is to be increased and the convenience is to be debased.

Many capacitive sensing is derived from the charge and discharge of the capacitor. The capacitance can be inferred according to charge and discharge time required, so that the distance variation of the proximity object can be inferred.

The common method such as sensing electrode electrically connected with RC circuit (resistor-capacitor circuit). The RC circuit utilizes the constant voltage or/and constant current to charge or discharge the capacitor. When the object closed to induce the capacitor to generate the induced capacitance variation, the induced capacitance variation will change the original time constant (no object is to be closed), and charge and discharge time of the system. The induced capacitance variation can be measured by many methods, for example, a comparator and a reference potential are used to confirm the induced capacitance change.

The second method such as the sensing electrode is electrically connected with the tuned circuit. When the sensing electrode induces the capacitance variation, the oscillation frequency of the tuned circuit is slightly changed. The capacitance variation can be monitored by many methods.

Another method is that the charge on the sensing electrode is transferred to the reference capacitor. This circuit utilizes the constant voltage or/and constant current to charge and discharge the sensing electrode and the reference capacitor. When the object closed to the sensing electrode to induce the capacitance variation, the potential of the reference capacitor is to be changed. The potential variation can be determined by many methods. In general, a comparator and a reference potential are used to confirm the potential variation.

The problem with existing designs for the capacitive proximity sensing and positioning includes:
1. The RF signal is easily generated or the capacitive proximity sensing is easily affected by the RF signal.
2. The sensing is interfered by the moisture. The induction cannot be operated in humid environment.
3. The poor SNR, the lower sensitivity, the small variation of the induced capacitance of the large object cannot be monitored, or the small capacitance variation cannot be monitored due to the large background capacitive environment is generated by the large object.
4. The resistance of the ITO on the sensing electrode will be influenced when the capacitive proximity sensing is designed as the touch panel.
5. The influence of the leakage current.
6. Higher cost.

Please refer to FIG. 21. FIG. 21 is a schematic diagram of showing a greater linear error that is generated in the periphery by a conventional capacitive sensing electrode. As shown in FIG. 21, the plurality of capacitive sensing electrode 503 is an independent matrix 502 which is arranged by each capacitive sensing electrode 503 with the same size and shape. The drawback of the conventional independent matrix 502 is that, if the interpolation method is used to perform drawing and positioning functions in the conventional independent matrix 502, the greater linearity error will be generated in the outermost area, for example, draw a straight line will produce a linearity error such as offset lines 500. The arrangement of the capacitive sensing electrode is an independent matrix 502 in FIG. 21. In addition, the intersection matrix of row and column sensing electrode of another conventional application also has the same drawback as the above discussion.

In view of above drawbacks in the conventional prior art, applicant provides a charged body sensing system. By the output signal variation of the filter is detected by the detector to obtain the trajectory, the velocity or the location of the charged body, or an impedance variation of the charged body sensing unit.

### SUMMARY OF THE INVENTION

An objective of the present invention is to provide a charged body sensing system. Thus, the output signal variation of the filter can be detected by the detector to obtain the trajectory, the velocity or the location of the charged body, or an impedance variation of the charged body sensing unit.

According to above object, the present invention provides a charged body sensing system. The system includes a signal generator, which generates at least an excitation signal, a filter, which is coupled to the signal generator. The filter receives the excitation signal from the signal generator. The filter further includes at least a resonant circuit, which includes at least one charged body sensing unit. The charged body sensing unit includes at least a charged body sensing electrode and an impedance element. The system also includes a detector, which is coupled to the filter. The detector detects an output signal of the charged body sensing unit. The charged body sensing unit includes a charged body sensing electrode, which sense the state in the surface or adjacent region of the charged body sensing electrode. When the charged body sensing electrode nears or touches the charged body sensing electrode, the output signal of the filter corresponding to the charged body sensing electrode will be changed. Thus, the change of the output signal of the filter can be detected by the detector to obtain the trajectory, the velocity or the location of the charged body, or an impedance variation of the charged body sensing unit.

### BRIEF DESCRIPTION OF THE DRAWINGS

The present invention will be apparent to those skilled in the art by reading the following description of a preferred embodiment thereof with reference to the drawings, in which:

FIG. 1 is a block view showing a first embodiment in accordance with the present invention.

FIG. 2 is a block view showing a charged body which is neared or touched in the first embodiment in accordance with the present invention.

FIG. 3 is a schematic diagram showing a transfer function of the filter in the first embodiment in accordance with the present invention.

FIG. 4 is a schematic diagram showing another transfer function of the filter in the first embodiment in accordance with the present invention.

FIG. 5 is a schematic diagram showing a transfer function corresponding to the charged body nears or touches the charged body sensing electrode in the first embodiment in accordance with the present invention.

FIG. 6 is a schematic diagram showing an equivalent circuit in a first embodiment in accordance with the present invention.

FIG. 7a is a schematic diagram showing a parallel equivalent circuit is composed by a charged body sensing electrode and an input capacitance of the detector in accordance with the present invention.

FIG. 7b is a schematic diagram showing a parallel equivalent circuit of FIG. 7a in accordance with the present invention.

FIG. 7c is a schematic diagram showing a series equivalent circuit of FIG. 7a in accordance with the present invention.

FIG. 8a is a schematic diagram showing an equivalent circuit which is formed by the charged body closed the charged body sensing electrode and the input capacitance of the detector in accordance with the present invention.

FIG. 8b is a schematic diagram showing an equivalent circuit of FIG. 8a in accordance with the present invention.

FIG. 8c is a schematic diagram showing a parallel equivalent circuit of FIG. 8a in accordance with the present invention.

FIG. 8d is a schematic diagram showing a series equivalent circuit of FIG. 8a in accordance with the present invention.

FIG. 9a is a schematic diagram showing an equivalent circuit of FIG. 6 in accordance with the present invention.

FIG. 9b is a schematic diagram showing a waveform of the voltage function V(f) of FIG. 9a in accordance with the present invention.

FIG. 10a is a schematic diagram showing an equivalent circuit after the charged body closes to the charged body sensing electrode of FIG. 9 in accordance with the present invention.

FIG. 10b is a schematic diagram showing a waveform of the voltage function V_{T}(f) of FIG. 10a in accordance with the present invention.

FIG. 11a is a schematic diagram showing a voltage function v(t) in a time domain of FIG. 9b in accordance with the present invention.

FIG. 11b is a schematic diagram showing a voltage function v_{T}(t) in a time domain of FIG. 10b in accordance with the present invention.

FIG. 12 is a schematic diagram showing a charged body closes to the charged body sensing electrode from far to near in accordance with the present invention.

FIG. 13 is a schematic diagram showing the voltage variation between V(f₀) and V_{T}(f₀) in FIG. 9b and FIG. 10b in accordance with the present invention.

FIG. 14 is a schematic diagram showing a block schematic of the internal component of the filter in a first embodiment in accordance with the present invention.

FIG. 15 is a schematic diagram showing a block schematic of the internal component of the charged body sensing unit in a first embodiment in accordance with the present invention.

FIG. 16 is a schematic diagram showing an equivalent circuit in a second embodiment in accordance with the present invention.

FIG. 17 is a block schematic showing a third embodiment in accordance with the present invention.

FIG. 18 is a schematic diagram showing a plurality of charged bodies touches the plurality of charged body sensing electrodes in a third embodiment in accordance with the present invention.

FIG. 19 is a schematic diagram showing a waveform of the excitation signal corresponding to the output signal in accordance with the present invention.

FIG. 20 is a schematic diagram showing a plurality of charged body sensing electrodes arrange on the display in a fourth embodiment in accordance with the present invention.

FIG. 21 is a schematic diagram showing a boundary error which is generated by a capacitive sensing electrode in accordance with the conventional prior art.

FIG. 22 is a block schematic showing a fifth embodiment in accordance with the present invention.

FIG. 23 is a schematic diagram showing the usage of a charged body sensing electrode in accordance with the present invention.

### DETAILED DESCRIPTION OF THE PREFERRED EMBODIMENT

The present invention is used to measure the impedance, and is also applied to measure the coupling capacitance change, the electromagnetic field change and the impedance, which are induced by nearing or touching the charged body sensing electrode 211. Those changes will change the transfer function 220 of the filter. The impedance to be measured that can be inferred by the changes of the transfer function 220. In addition, the proximity and location of the charged body 40 can also be inferred.

### First Embodiment

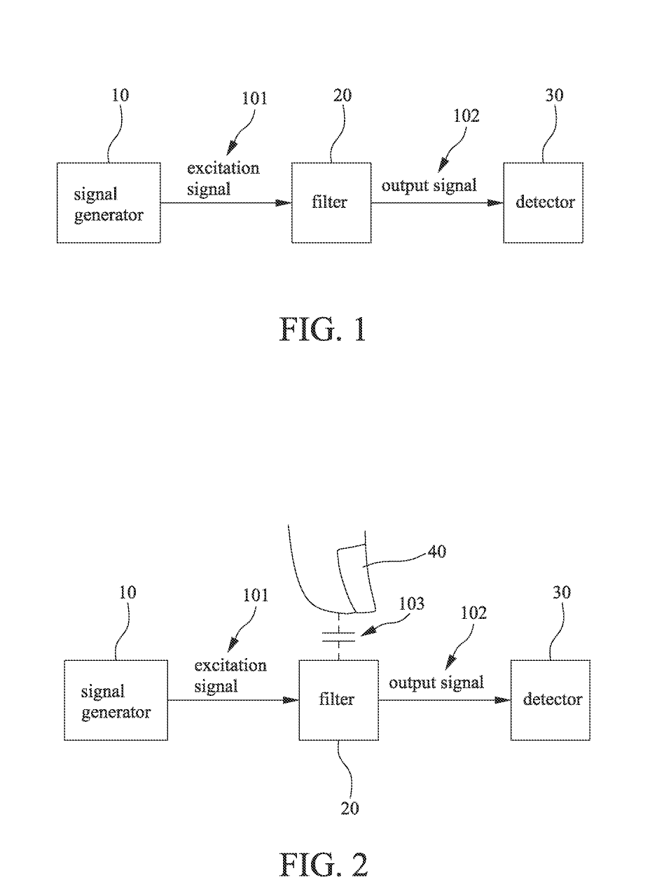

Please refer to FIG. 1 to FIG. 15. A charged body sensing system includes a signal generator 10, a filter 20, and a detector 30. The signal generator 10 generates at least one excitation signal 101. The signal generator 10 is coupled to the filter 20, and the filter 20 receives the excitation signal 101 from the signal generator 10. The filter 20 includes at least one resonant circuit 200, and the resonant circuit 200 includes at least one charged body sensing unit 21. The charged body sensing unit 21 includes at least a charged body sensing electrode 211 and at least an impedance element 210. The filter 20 is coupled to the detector 30. The detector 30 is corresponding to an output signal of the charged body sensing unit 21 of the filter 20. An induced capacitance 103 is generated when the charged body neared or touched to the charged body sensing electrode 211, an output signal 102 of the charged body sensing unit 21 corresponding to the induced capacitance will be changed. The detector 30 detects the output signal variation of the filter 20 to determine to obtain the trajectory, the velocity or the location of the charged body, or an impedance variation of the charged body sensing unit 21. In addition, the detector 30 includes at least one frequency response detector, and each frequency response detector detects the magnitude or the phase of the transfer function 220 of the filter 20.

The signal generator 10 includes at least one signal generator 10. The signal generator 10 transmits at least one excitation signal 101 to the filter 20. The signal generator 10 generates at least one excitation signal 101. The excitation signal 101 includes at least a period of periodic signal. The way of the connection between the signal generator 10 and the filter 20 by broadcasting, electromagnetic coupling, capacitive coupling, photo-coupling, sonic-coupling or electrical contacting directly.

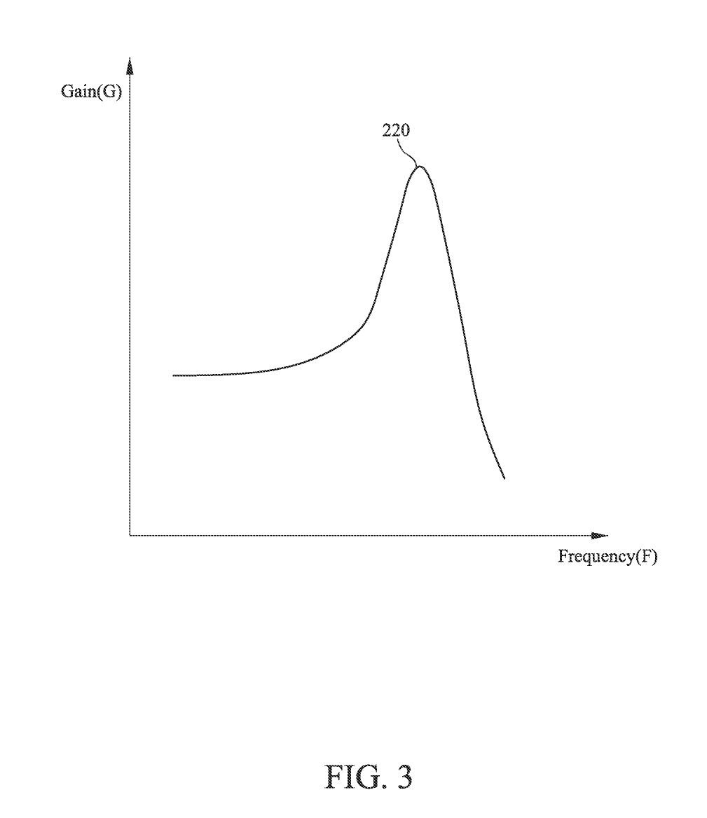

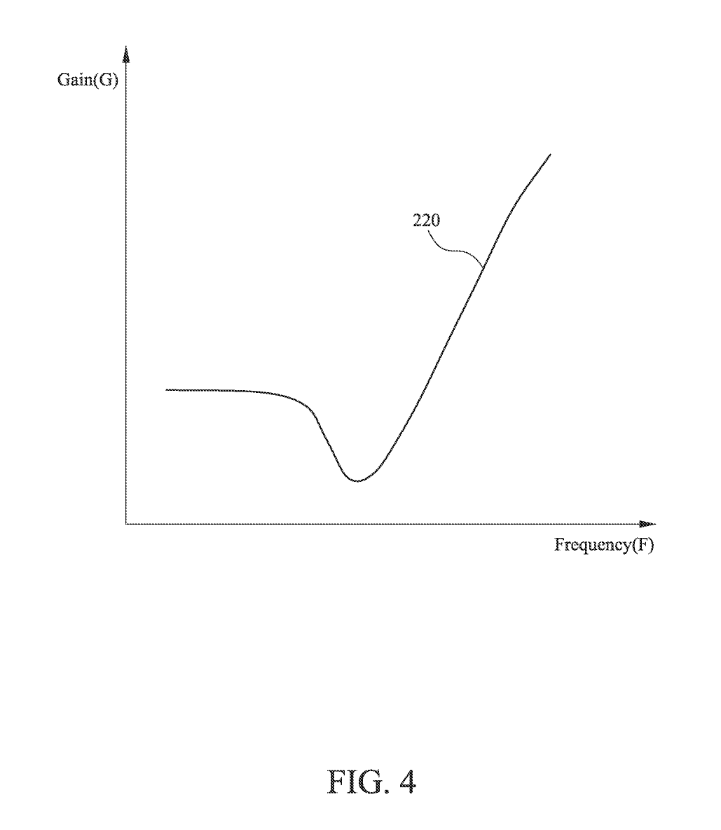

The filter 20 includes at least a filter 20. The filter 20 can be an active filter or a passive filter. The filter 20 can be regard as the linear time-invariant systems. The filter 20 includes at least a charged body sensing unit 21. The transfer function 220 of the filter includes at least a quadratic polynomial. The quadratic polynomial is a factor of the transfer function 220 of the filter 20. When the transfer function 220 of the filter 20 is the reciprocal of the quadratic polynomial, the transfer function 220 of the filter 20 as shown in FIG. 3. In addition, when the transfer function 220 of the filter 20 is a quadratic function, the transfer function 220 of the filter 20 as shown in FIG. 4.

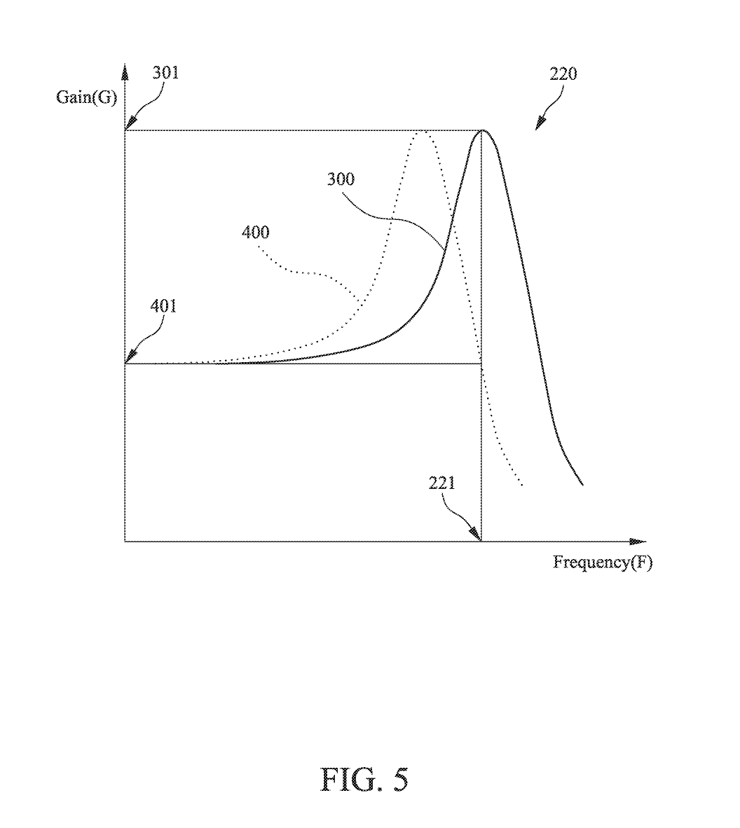

Please refer to FIG. 5. FIG. 5 shows a transfer function 220 corresponding to the charged body 40 nears or touches to the charged body sensing electrode 211. When the charged body 40 neared or touched the charged body sensing electrode 211, the transfer function 220 of the filter 20 will be changed. When the charged body 40 is not neared or touched the charged body sensing electrode 211, the transfer function 220 of the filter 20 is transfer function 300. When the charged body 40 is neared or touched the charged body sensing electrode 211, the transfer function 220 of the filter 20 is transfer function 400. When the excitation signal frequency (1/T) 221 is fixed, and the charged body 40 is neared or touched to the charged body sensing electrode 211, the amplitude of the output signal 102 of the filter 20 will be changed. When the charged body 40 is not neared or touched the charged body sensing electrode 211, the maximum gain of the transfer function 220 of the filter 20 is gain 301. When the charged body 40 is neared or touched the charged body sensing electrode 211, the minimum gain of the transfer function 220 of the filter 20 is gain 401.

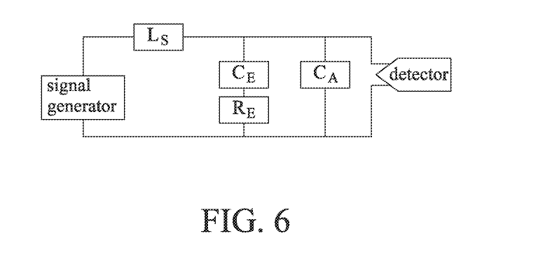

Please refer to FIG. 6. FIG. 6 shows an equivalent circuit in a first embodiment. C_{E} and R_{E} expresses the equivalent circuit of the charged body sensing electrode 211 respectively, in which C_{E} is an equivalent capacitance, R_{E} is an equivalent resistance, and C_{A} is an input capacitance of the detector 30. The filter 20 is composed by an inductance L_{S}, the equivalent capacitance C_{E}, the equivalent resistance and the input capacitance of the detector 30.

There are many methods for measuring the variance or the value of the passive component. When the excitation signal frequency, the inductance and the resistance are constant, the capacitance of the charged body sensing electrode 211 will be changed when the human body is neared or touched the charged body sensing electrode 211. The capacitance and the variation can be inferred by the changes in the voltage of the charged body sensing electrode 211 which is detected by the detector 30.

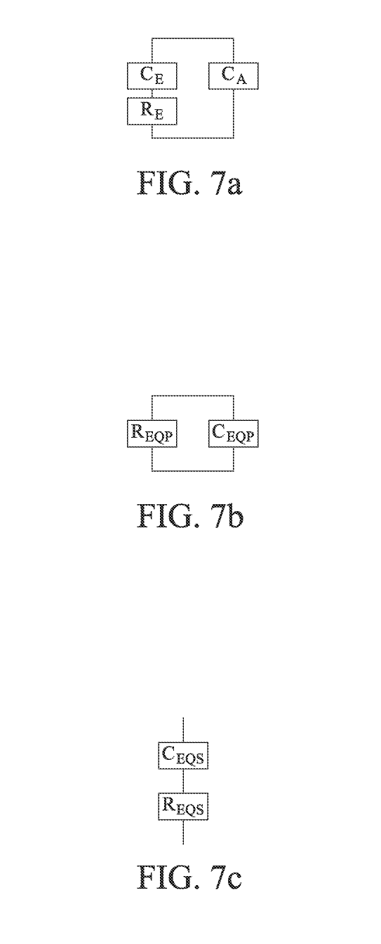

FIG. 7a is a schematic diagram showing a parallel equivalent circuit is composed by a charged body sensing electrode 211 and an input capacitance of the detector 30; FIG. 7b is a schematic diagram showing a parallel equivalent circuit of FIG. 7a; and FIG. 7c is a schematic diagram showing a series equivalent circuit of FIG. 7a.

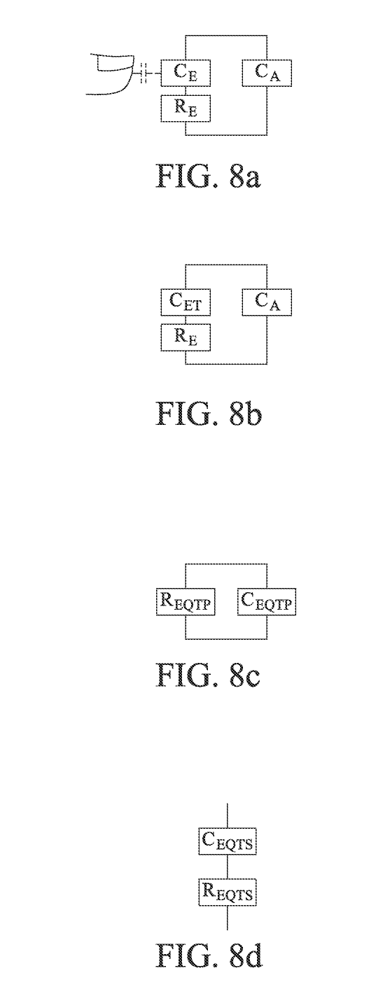

FIG. 8a is a schematic diagram showing an equivalent circuit which is formed by the charged body 40 closed to the charged body sensing electrode 211 and the input capacitance of the detector 30.

FIG. 8b is a schematic diagram showing an equivalent circuit of FIG. 8a. The induced capacitance is generated between the finger and the charged body sensing electrode 211 which is getting larger when the finger is getting closer and closer. The equivalent capacitance C_{ET} is composed by the induced capacitance and C_{E}.

FIG. 8c is a schematic diagram showing a parallel equivalent circuit of FIG. 8a. FIG. 8c shows the equivalent resistance R_{EQTP} and equivalent capacitance C_{EQTP} in parallel.

FIG. 8d is a schematic diagram showing a series equivalent circuit of FIG. 8a. FIG. 8d shows an equivalent resistance R_{EQTS} and the equivalent capacitance C_{EQTS} in series.

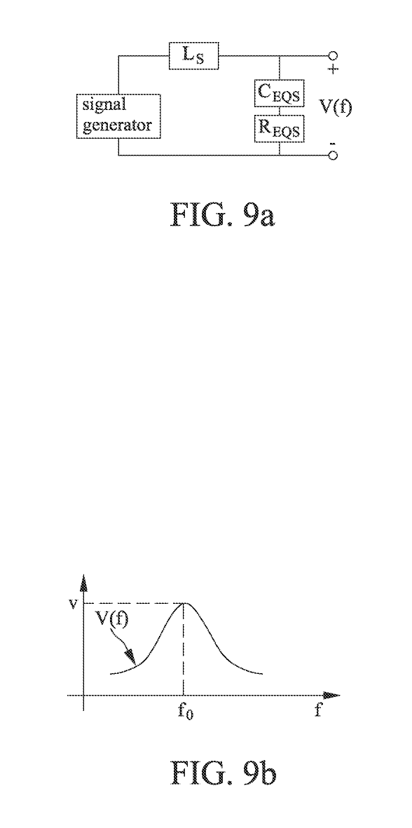

FIG. 9a is a schematic diagram showing an equivalent circuit of FIG. 6. FIG. 9a shows a series resonant circuit. The band-pass filter is formed by Ls, C_{EQS}, and R_{EQS}. The signal generator 10 generates a period of periodic signal or a plurality of periodic signal. The signal is not limited to the waveform. Alternatively, the signal is formed by a Sine wave or a plurality of Sine waves with different frequencies. The frequency transfer function of the filter 20 is detected by changing the signal content. In FIG. 9a, the voltage of the charged body sensing electrode 211 in the band-pass filter is detected by the detector 30. The voltage is a frequency related function V(f). The waveform of the voltage function V(f) as shown in FIG. 9b, in which f₀ is a center frequency (resonant frequency) of the resonant circuit, and the formula can be illustrated as

$${f}_{0} = \frac{1}{2 π \sqrt{{L}_{S} {C}_{EQS}}} ,$$

when f=f₀, the voltage in the charged body sensing electrode 211 is V(f₀), and now the voltage is maximum value. Q_{S} is Q value of the circuit, and the formula can be illustrated as

$${Q}_{S} = \frac{\sqrt{\frac{{L}_{S}}{{C}_{EQS}}}}{{R}_{EQS}} .$$

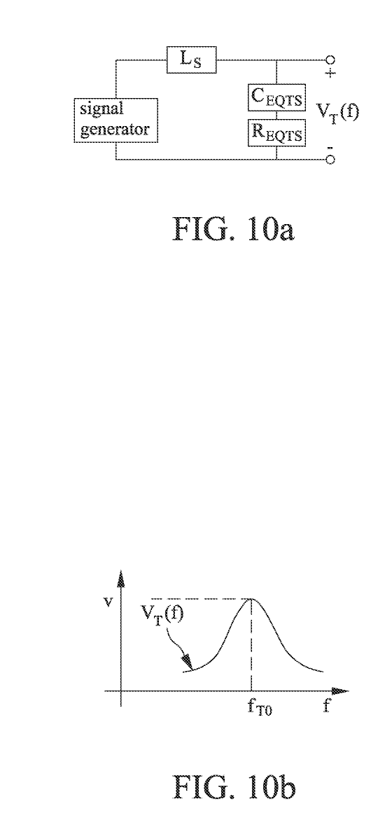

FIG. 10a is a schematic diagram showing an equivalent circuit after the charged body 40 nears or touches the charged body sensing electrode 211 of FIG. 9. The equivalent circuit forms a series resonant circuit. The Ls, C_{EQTS}, and R_{EQTS} forms a band-pass filter. The voltage of charged body sensing electrode 211 can be detected by the detector 30. The voltage is a frequency related function V_{T}(f). f_{T0} is a center frequency of the resonant circuit, and the formula can be illustrated as

$${f}_{T 0} \frac{1}{2 π \sqrt{{L}_{S} {C}_{EQTS}}} ,$$

when f=f_{T0}, the voltage in the charged body sensing electrode 211 is V(f_{T0}), and now, the voltage is maximum value. Q_{TS} is Q value of the circuit, and the formula can be illustrated as

$${Q}_{TS} = \frac{\sqrt{\frac{{L}_{S}}{{C}_{EQTS}}}}{{R}_{EQTS}} .$$

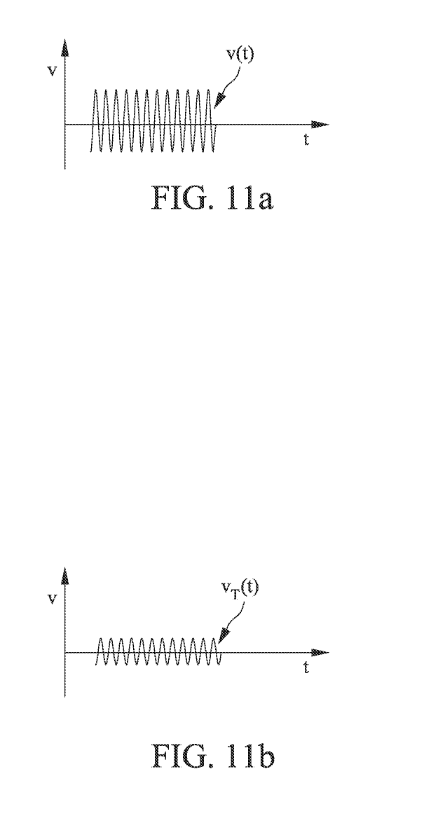

FIG. 11a is a schematic diagram showing a voltage function v(t) in a time domain of FIG. 9b. When the signal generator 10 transfers a signal of frequency f₀, the peak of v(t) is V(f₀).

FIG. 11b is a schematic diagram showing a voltage function v_{T}(t) in a time domain of FIG. 10b. When the signal generator 10 transfers a signal of frequency f₀, peak of v_{T}(f) is V_{T}(f₀), f₀≠f_{T0}. Now, the peak of the voltage v_{T}(t) is not maximum value.

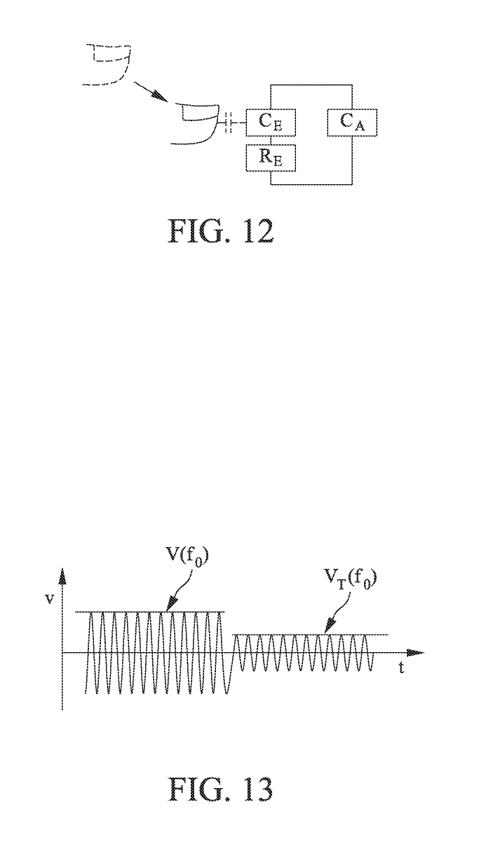

FIG. 12 is a schematic diagram showing a charged body 40 closes to the charged body sensing electrode 211 from far to near. If the signal generator 10 transfers a periodic signal of frequency f₀, when the charged body 40 closes to the charged body sensing electrode 211, the voltage variation of the charged body sensing electrode 211 is to be changed as shown in FIG. 13. Now, the signal-to-noise ratio is the highest. Thus, the distance between the charged body 40 and the charged body sensing electrode 211 can be inferred by the voltage variance between V(f₀) and V_{T}(f₀).

The different output signal 102 can be obtained when the filter 20 is disposed in different environment, at different time, or component of filter 20 is to be changed at the same excitation signal 101.

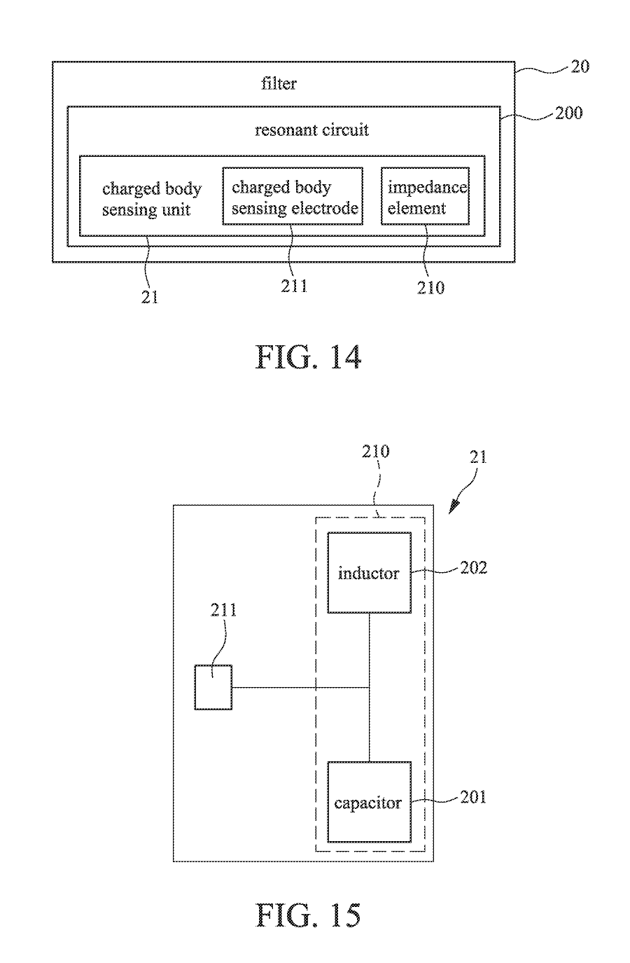

Please refer to FIG. 14. FIG. 14 is a schematic diagram showing a block schematic of the internal component of the filter 20. The filter 20 includes at least a resonant circuit 200. The resonant circuit 200 includes at least a charged body sensing unit 21. The charged body sensing unit 21 includes at least a charged body sensing electrode 211 and at least an impendance element 210. Next, please refer to FIG. 15. The charged body sensing unit 21 includes an inductor 202, a capacitor 201 and a charged body sensing electrode 211. As shown in FIG. 15, the inductor 202 and a capacitor 201 are arranged in series connection, and charged body sensing unit 211 is coupled to the connection point between the inductor 202 and the capacitor 201. The inductor 202 can be a passive inductor component or an active inductor component.

### Second Embodiment

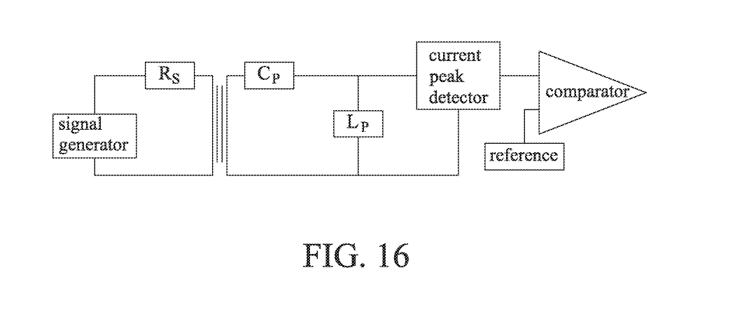

Please refer to FIG. 16. FIG. 16 is a schematic diagram showing an equivalent circuit in a second embodiment. The filter 20 is composed by an inductor Lₚ, a capacitor Cₚ and an input capacitance of current peak detector. The filter 20 is a LC band-pass filter. The signal generator 10 is a square wave generator, and the frequency is a center frequency of the band-pass filter. The signal transfer path is an electromagnetic coupling path. The filter 20 receives a coupled current signal. Now, the filter 20 is a LC parallel resonant circuit. When the excitation signal frequency equals to the resonant frequency of the filter 20, the signal-to-noise ratio and the sensitivity are the highest.

The coupling capacitance would be generated when the charged body 40 nears or touches the signal transfer path or the filter 20. The coupling capacitance will change the equivalent capacitance of the parallel resonant circuit, so as to the resonant frequency is to be changed. The capacitance variation is induced by the charged body 40 that will change the resonant frequency slightly. When the frequency of the excitation signal 101 is maintained in a resonant frequency in an initial state (for example, the charged body 40 is not close to the signal transfer path or the filter 20), the attenuation of the output function of the filter 20 is very seriously, although the resonant frequency of the filter 20 is changed slightly.

The function of each component as described can be integrated into a single device, such as an IC chip. Alternatively, each component can be formed a single device respectively, and the plurality of devices is integrated into a system. For example, a signal generator 10 is disposed in the mobile phone base stations, and the filter 20 and the detector 30 are designed in the mobile phone.

For example, a signal with a fixed frequency and amplitude is communicated into the different filter, and the variation of frequency transform function can be obtained from the output signal variation of each filter. Alternatively, the signal is transferred to the same filter 20 at the different times to obtain the frequency response variation of the filter 20 vary with the time or vary with the environment.

When the component is changed at the output impedance of signal generator 10, the transfer path between the signal generator 10 and the filter 20, and the input impedance of the detector 30, the transfer function will be changed. The component variation can be inferred by the transfer function variation which is introduced by the output signal 102 of the filter 20. In other word, the charged body sensing electrode 211 can dispose on above site of the component. Alternatively, the layout and the parts of the component on above site can be used as the charged body sensing electrode 211 in the field of the proximity sensing and the location positioning.

The detector 30 detects the output signal 102 of the filter 20. The transfer function 220 can be introduced by the output signal 220. The detector 30 can be a voltage analog-to-digital converter, a current analog-to-digital converter, a rectifier, a voltmeter, or a peak detector.

In view of above, the charged body sensing system of the present invention is not subject to interference of the radio frequency signals, the noise, the moisture, higher resistance at the sensing electrode, and the leakage current. In addition, the charged body sensing system of the present invention is low cost and easy to manufacture.

### Third Embodiment

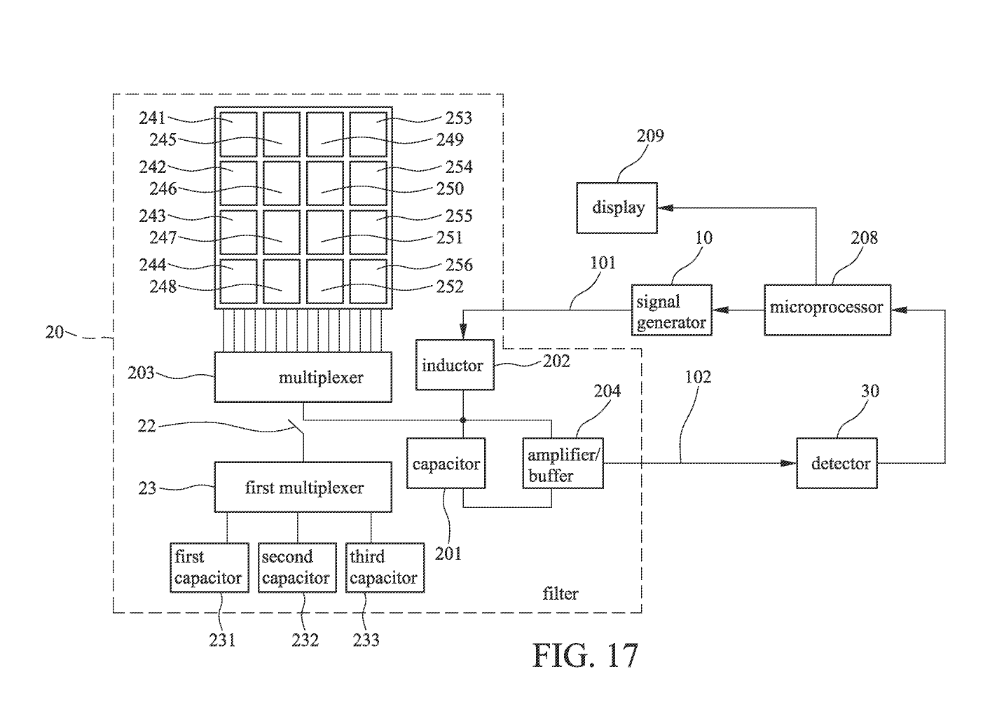

Please refer to FIG. 17 to FIG. 19. FIG. 17 to FIG. 19 shows a further embodiment of the present invention. The filter 20 further includes a capacitor 201, an inductor 202, a multiplexer 203 and an amplifier/buffer 204. The amplifier/buffer 204 is provided for impedance transformation from the filter 20 to the detector 30 and amplifying the signal. The capacitor 201 is electrically connected with the inductor 202. The multiplexer 203 is electrically between the capacitor 201 and the inductor 202. The multiplexer 203 is electrically connected with the plurality of charged body sensing electrode 211. The signal generator 10 is coupled to the inductor 202. The filter 20 receives the excitation signal 101 from the signal generator 10. The amplifier/buffer 204 outputs an output signal 102 to the detector 30.

The detector 30 includes an analog-to-digital converter. The detector 30 is further electrically connected with a microprocessor 208. The microprocessor 208 is electrically connected with the signal generator 10 and a monitor 209, in which the signal generator 10 includes an analog-to-digital converter.

The multiplexer 207 is electrically connected with a first charged body sensing electrode 241, a second charged body sensing electrode 242, a third charged body sensing electrode 243, a fourth charged body sensing electrode 244, a fifth charged body sensing electrode 245, a sixth charged sensing electrode 246, a seventh charged body sensing electrode 247, a eighth charged body sensing electrode 248, a ninth charged body sensing electrode 249, a tenth charged body sensing electrode 250, a eleventh charged body sensing electrode 251, a twelfth charged body sensing electrode 252, a thirteenth charged body sensing electrode 253, a fourteenth charged body sensing electrode 254, a fifteenth charged body sensing electrode 255, and a sixteenth charged body sensing electrode 256 as shown in FIG. 17.

In third embodiment of the present invention, each charged body sensing electrode 211 corresponding to the excitation signal 101 is provided with different operating frequencies, such that the different charged body sensing electrode 211 is provided with a consistent relationship between the amplitude and frequency and consistent of the sensitivity.

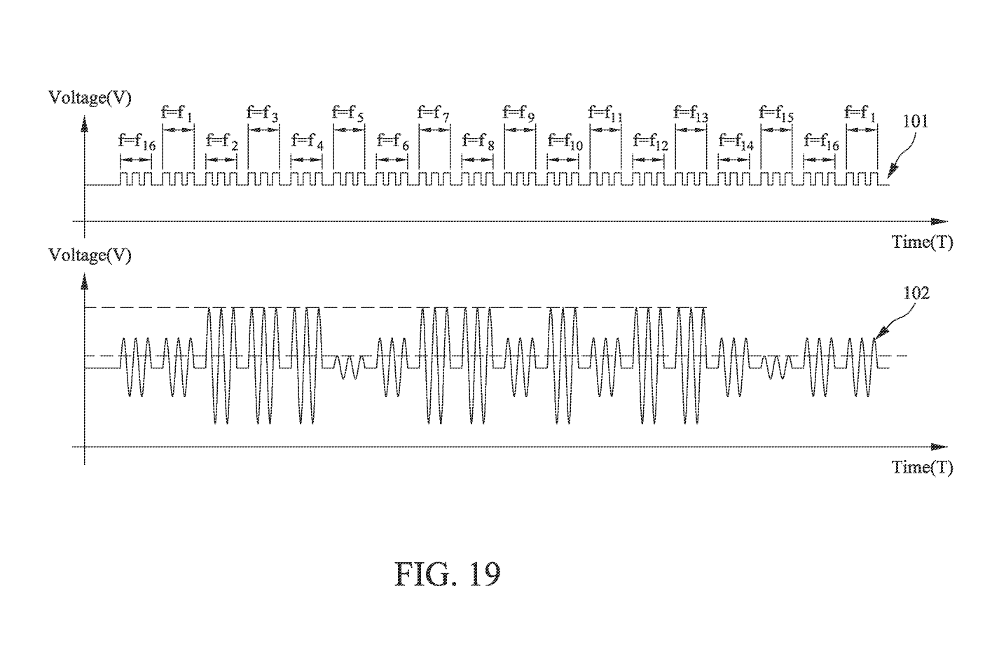

As shown in FIG. 19, the frequency of the excitation signal 101 corresponding to the first charged body sensing electrode 241 is set to f₁, the frequency of the excitation signal 101 corresponding to the second charged body sensing electrode 242 is to f₂, the frequency of the excitation signal 101 corresponding to the third charged body sensing electrode 243 is to f₃, the frequency of the excitation signal 101 corresponding to the fourth charged body sensing electrode 244 is set to f₄, the frequency of the excitation signal 101 corresponding to the fifth charged body sensing electrode 245 is set to f₅, the frequency of the excitation signal 101 corresponding to the sixth charged body sensing electrode 246 is set to f₆, the frequency of the excitation signal 101 corresponding to the seventh charged body sensing electrode 247 is set to f₇, the frequency of the excitation signal 101 corresponding to the eighth charged body sensing electrode 248 is set to f₈, the frequency of the excitation signal 101 corresponding to the ninth charged body sensing electrode 249 is set to f₉, the frequency of the excitation signal 101 corresponding to the tenth charged body sensing electrode 250 is set to f₁₀, the frequency of the excitation signal 101 corresponding to the eleventh charged body sensing electrode 251 is set to f₁₁, the frequency of the excitation signal 101 corresponding to the twelfth charged body sensing electrode 252 is set to f12, the frequency of the excitation signal 101 corresponding to the thirteenth charged body sensing electrode 253 is set to f₁₃, the frequency of the excitation signal 101 corresponding to the fourteenth charged body sensing electrode 254 is set to f₁₄, the frequency of the excitation signal 101 corresponding to the fifteenth charged body sensing electrode 255 is set to f₁₅, and the frequency of the excitation signal 101 corresponding to the sixteenth charged body sensing electrode 256 is set to f₁₆, such that the gain of the transfer function 220 corresponding to the charged body sensing electrode 211 is provided with charged body sensing and the impedance measuring is between the gain 301 and gain 401.

The multiplexer 203 is electrically connected with a switch 22. The switch 22 is electrically connected with a first multiplexer 23, and the first multiplexer 23 is electrically connected with a first capacitor 231, a second capacitor 232 and a third capacitor 233. As shown in FIG. 17, the first multiplexer 23 is electrically connected with the first capacitor 231, the second capacitor 232, and the third capacitor 233. The first multiplexer 23 has three operating adjustment frequencies respectively. By controlling the first multiplexer 23 and switch 22, another capacitor may be or may not be added into the circuit of the capacitor 201. During appropriate design, the first multiplexer 23 can be adjusted to obtain four operating frequencies, such that the operating frequency can be changed at designated time or at variable interval time to decrease the noise interference in third embodiment of the present invention.

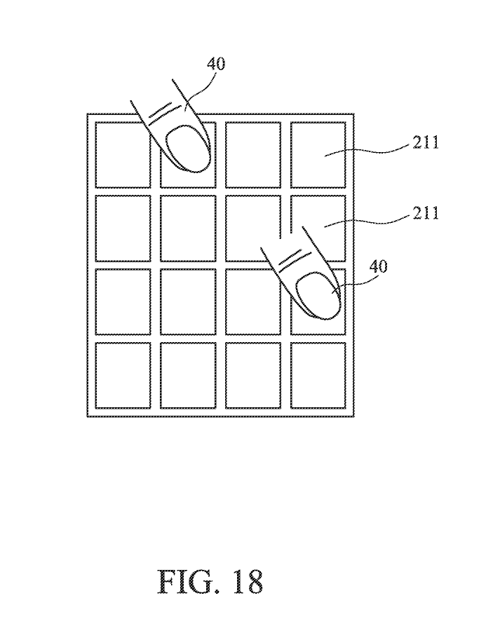

Please refer to FIG. 18 and FIG. 19. When the plurality of charged body 40 touches the plurality of charged body sensing electrode 211 (as shown in FIG. 18). In addition, please also refer to FIG. 19. FIG. 19 is a schematic diagram showing an output signal 102 of the filter 20.

When the output signal 102 of the filter 20 is passed through the detector 30, the amplitude change of the output signal 102 of each charged body sensing electrode 211 can be obtained by the microprocessor 208 during the operating. In addition, the linear correction of the charged body sensing system can be corrected by the microprocessor 208.

When the plurality of charged bodies 40 nears or touches the plurality of charged body sensing electrode 211, the location and the trajectory of the charged body 40 can be determined by interpolation of the amplitude of the output signal 201 corresponding to each charged body sensing electrode 211. In which, the charged body sensing electrode 211 can be arranged on the display 209 by the way of planar array. In order to decrease the cost and the thickness of the product, the charged body sensing electrode 211 can be designed to combine the interior of the display 209.

### Fourth Embodiment

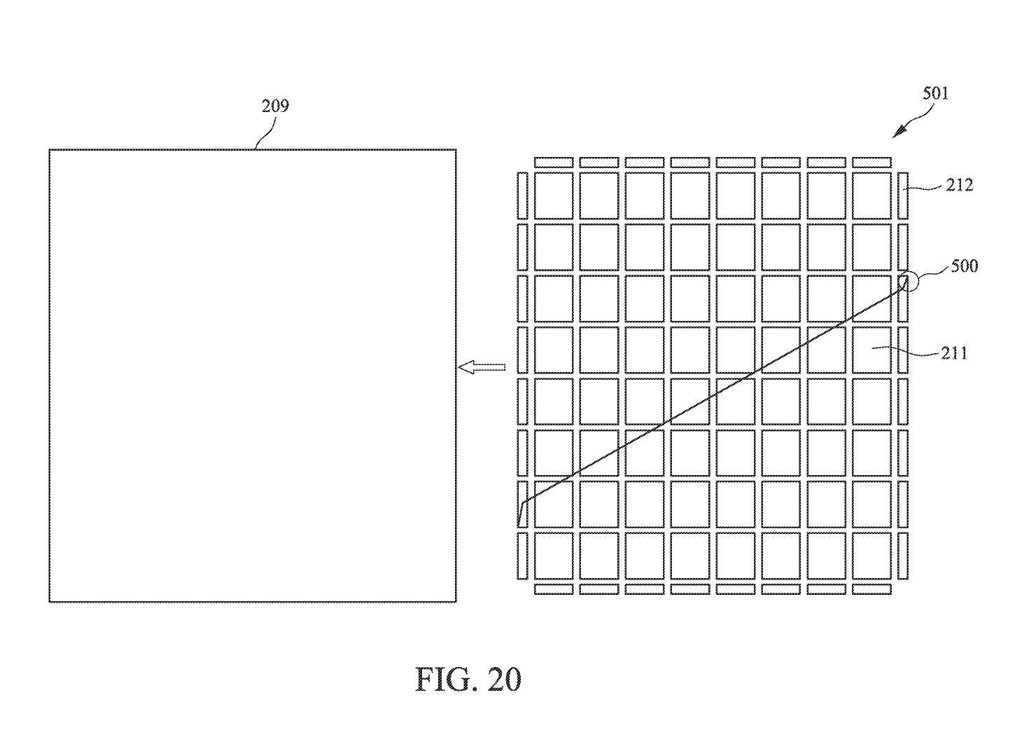

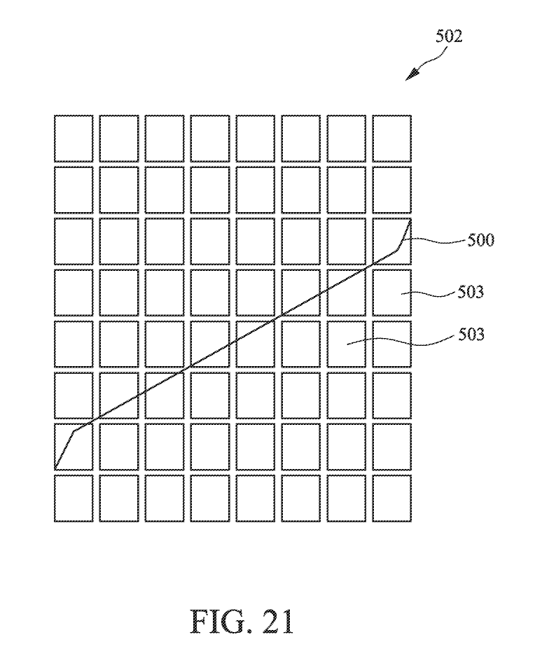

Please refer to FIG. 20. FIG. 20 shows a plurality of charged body sensing electrodes that arranged on the monitor of the fourth embodiment. There are many kinds of the arrangement for the charged body sensing electrode 211. The arrangement of the plurality of charged body sensing electrodes 211 can be planar matrix or three-dimensional matrix. In addition, the plurality of charged body sensing electrode 211 is formed by arranging a plurality of charged body sensing electrode 211 with different sizes or different shapes.

The plurality of charged body sensing electrodes 211 is further stacked on the display 209. The plurality of charged body sensing electrodes is arranged to form a charged body sensing electrode matrix 501 on the display 209. The outer region of the charged body sensing electrode matrix 501 is provided with a plurality of charged body sensing electrodes 212, and the inner region of the charged body sensing electrode matrix 501 is provided with a plurality of charged body sensing electrodes 211. The area of each charged body sensing electrode 212 is smaller than that of each charged body sensing electrode 211. The linear error of the outer region of the charged body sensing electrode matrix 501 is decreased with when the ratio between the areas of each charged body sensing electrode 212 corresponding to each charged body sensing electrode 211 is shrunk, Thus, the border area of the display 209 can be reduced and the linearity error of the outer region of the charged body sensing electrode matrix 501 can also be decreased.

### Fifth Embodiment

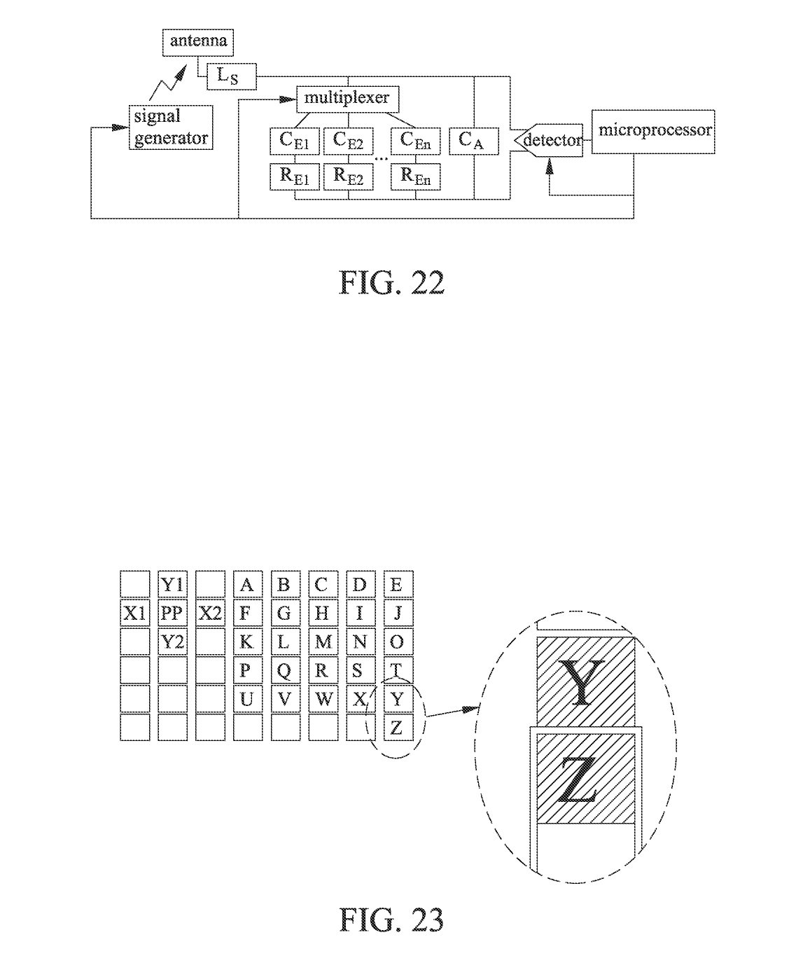

Finally, please refer to FIG. 22. FIG. 22 shows a block diagram of the fifth embodiment of the present invention. The signal is emitted from the signal generator 10 by the wireless, and the filter 20 receives the signal. The multiplexer is electrically connected the specific charged body sensing electrode with the filter 20 by the microprocessor. The voltage on the charged body sensing electrode 211 can be detected by the detector 30.

In view of above, the microprocessor can determine the charged body sensing system as:

1. Which charged body sensing 211 electrodes being used and being detected.

2. The resonant frequency that could be different when each charged body sensing electrode is added into the filter, the microprocessor controls and memorizes the frequency of the excitation signal 101 corresponding to the charged body sensing electrode 211 which is transferred from the signal generator 10.

3. The voltage of each charged body sensing electrode 211 can be detected and recorded, so that the location of the charged body 40 can be inferred.

FIG. 23 is a schematic diagram showing the usage of the charged body sensing electrode 211. FIG. 23 shows an array arrangement for the plurality of charged body sensing electrodes 211. In FIG. 23, each small box represents a charged body sensing electrode 211. The English letters of the alphabet is clearly visible and the convenience for discussion. On the right side of FIG. 23 shows the enlarge diagram of the Y and Z, two charged body sensing electrodes 211 respectively.

In fifth embodiment of the present invention, we can obtain: 1. by the difference between the voltages of B, F, L, and H, and the other charged body sensing electrodes 211, the charged body 40 on region G can be inferred, and the location of the charged body 40 can be positioned.

By the difference between the voltages of G, K, M and Q and the other charged body sensing electrodes 211, the charged body 40 on region L can be inferred, and the location of charged body 40 can also be positioned

According to above manners, one or a plurality of charged bodies 40 closes to the charged body sensing electrode array can be inferred, and the coordination of the plurality of charged bodies 40 can also be inferred.

The relationship between the voltage which is obtained by the charged body sensing electrode 211 and the location of the charged bodies 40 may not be a linear relationship. There are many methods can solve the non-linear relationship. For example, a look up table is used for the calibration.

One aspect and the simple positioning method in this embodiment of the present invention is described as follows:
1. The voltage, VX1, VX2, VY1 and VY2 of X1, X2, Y1 and Y2 is to be detected.
2. The central coordinate of PP is assumed as (0, 0), the horizontal axis is X, and longitudinal axis is Y.
3. The X axis can be determined by formula:

$$\frac{VX 2 - VX 1}{VX 1 + VX 2} ,$$

Y axis can be determined by formula:

$$\frac{VY 2 - VY 1}{VY 1 + VY 2}$$

In view of above, the features of the present invention are described as follows.

The sensitive and signal-to-noise ratio of the present charged body sensing technology are higher than that of the conventional prior art.

The higher sensitive and higher signal-to-noise ratio of the present invention can reduce the system design difficult, improve the manufacturing yield, and reduce the cost of the touch panel.

The higher sensitive and higher signal-to-noise ratio of the present invention can reduce the operating voltage so as to reduce the system consumption.

The higher sensitive and higher signal-to-noise ratio of the present invention can reduce can reduce the linear error.

Although the present invention has been described with reference to the preferred embodiment thereof, it is apparent to those skilled in the art that a variety of modifications and changes may be made without departing from the scope of the present invention which is intended to be defined by the appended claims

What is claimed is:

1. A charged body sensing system, comprising:
a signal generator, which generates at least one excitation signal, said excitation signal includes at least a period of periodic signal;
a filter, which is coupled to said signal generator, said filter is provided for receiving said excitation signal from said signal generator, said filter includes at least a resonant circuit, said resonant circuit includes at least a charged body sensing unit, and said charged body sensing unit includes at least a charged body sensing electrode and at least an impedance element; and
a detector, which is coupled to said filter, said detector corresponding to an output signal of said filter, when said charged body nears or touches said charged body sensing electrode, said output signal corresponding to said filter is to be changed, said detector detects the variation of said output signal of said filter to obtain the trajectory, the velocity or the location of said charged body, or the impedance variation within said charged body sensing unit.

2. The charged body sensing system according to claim 1, wherein said signal generator includes a plurality of signal generators, each said plurality of signal generators transfers at least one excitation signal to said filter.

3. The charged body sensing system according to claim 1, wherein the way of said signal generator is coupled to said filter by broadcasting, the electromagnetic coupling, the capacitive coupling, the photo coupling, the sonic coupling, or electrical contacting directly.

4. The charged body sensing system according to claim 1, wherein said filter includes at least one charged body sensing unit, which enables a transfer function of said filter includes at least a quadratic polynomial.

5. The charged body sensing system according to claim 1, wherein said detector includes at least a frequency response detector, said frequency response detector detects the magnitude or the phase of a transfer function of said filter.

6. The charged body sensing system according to claim 1, wherein said filter further comprising a capacitor, an inductor, a multiplexer and an amplifier/buffer, said capacitor is electrically connected with said inductor, said multiplexer is electrically connected with between said capacitor and said inductor, said inductor is coupled to said signal generator, said filter receives said excitation signal of said signal generator corresponding to said amplifier/buffer to output said output signal to said detector.

7. The charged body sensing system according to claim 6, wherein said inductor includes a passive inductor or an active inductor.

8. The charged body sensing system according to claim 6, wherein said detector includes an analog-to-digital converter, which is electrically connected with a microprocessor, said microprocessor is electrically connected with said signal generator and a display.

9. The charged body sensing system according to claim 6, wherein said multiplexer is electrically connected with a switch, and said switch is electrically connected with a first multiplexer, wherein said first multiplexer is electrically connected with a first capacitor, a second capacitor and a third capacitor.

10. The charged body sensing system according to claim 1, wherein said charged body sensing electrode includes a plurality of charged body sensing electrodes, the arrangement of said plurality of charged body sensing electrodes is selected from the group consisting of a planar array and a three-dimensional array.

11. The charged body sensing system according to claim 1, wherein said charged body sensing electrode includes a plurality of charged body sensing electrodes, said plurality of charged body sensing electrodes is composed by a number of different sizes or different shapes of said charged body sensing electrodes.

12. The charged body sensing system according to claim 1, wherein said charged body sensing electrode includes a plurality of charged body sensing electrodes, said plurality of charged body sensing electrodes is stacked on a monitor, and said plurality of charged body sensing electrodes is arranged in a charged body sensing electrode array, an outer region of said charged body sensing electrode array includes a plurality of charged body sensing electrodes, and an inner region of said charged body sensing electrode array includes a plurality of charged body sensing electrodes, wherein the area of said outer region of each said charged body sensing electrodes is less than that of said inner region of each said charged body sensing electrodes.

13. The charged body sensing system according to claim 1, wherein said impedance element includes a passive impedance element or an active impedance element.
